(19) United States
(12) Patent Application Publication
(10) Pub. No.: US 2025/0118689 A1
(43) Pub. Date: Apr. 10, 2025

(54) SEMICONDUCTOR PACKAGE HAVING A CONTROLLER

(71) Applicant: SAMSUNG ELECTRONICS CO., LTD., SUWON-SI (KR)

(72) Inventors: Yongkwan Lee, Suwon-si (KR); Hyunki Kim, Suwon-si (KR); Youngmin Lee, Suwon-si (KR); Hyeon Hwang, Suwon-si (KR)

(21) Appl. No.: 18/782,386

(22) Filed: Jul. 24, 2024

(30) Foreign Application Priority Data
Oct. 6, 2023 (KR) 10-2023-0133626

(51) Int. Cl. H01L 23/00; H01L 25/18; H10B 80/00

(52) U.S. Cl. CPC H01L 24/04; H01L 24/16; H01L 24/48; H01L 24/73; H01L 24/32; H01L 25/18; H01L 2224/04042; H01L 2224/16225; H01L 2224/32145; H01L 2224/32225; H01L 2224/48227; H01L 2224/73265; H01L 2225/0651; H01L 2225/06562; H01L 2924/1431; H10B 80/00

(57) ABSTRACT

A semiconductor package includes a substrate having first and second sides, pads disposed on the substrate and including first and second bonding pads adjacent to the first and second sides, respectively, and upper pads between the first and second bonding pads, a passivation layer disposed on the substrate and exposing the first and second bonding pads, a solder resist layer disposed on the passivation layer, a first chip structure on the solder resist layer, adjacent to the first side and electrically connected to the first bonding pads, a second chip structure on the solder resist layer, adjacent to the second side and electrically connected to the second bonding pads, a controller on the solder resist layer between the first and the second chip structure, and a connection structure penetrating the passivation layer and the solder resist layer and electrically connecting the controller and the upper pads.

### CROSS-REFERENCE TO RELATED APPLICATION(S)

This application claims priority under 35 USC 119(a) to Korean Patent Application No. 10-2023-0133626, filed on Oct. 6, 2023, in the Korean Intellectual Property Office, the entire disclosure of which is herein incorporated by reference for all purposes.

### TECHNICAL FIELD

The present inventive concept relates to a semiconductor package, and more particularly to a semiconductor package having a controller.

### DESCRIPTION OF RELATED ART

Small and reliable semiconductor packages are used in electronic devices. Development of the semiconductor packages may improve the operation of the electronic devices. For example, a semiconductor package may include a plurality of semiconductor chips and a control chip controlling operations thereof.

### SUMMARY

Example embodiments provide a semiconductor package having improved miniaturization and reliability.

According to example embodiments, a semiconductor package includes a substrate having a first side and a second side opposing each other; and a plurality of pads disposed on the substrate. The plurality of pads include first bonding pads arranged adjacent to the first side, second bonding pads arranged adjacent to the second side, and upper pads disposed between the first bonding pads and the second bonding pads. A passivation layer is disposed on the substrate, wherein the passivation layer exposes the first bonding pads and the second bonding pads; a solder resist layer is disposed on the passivation layer of the substrate; a first chip structure on the solder resist layer, adjacent to the first side and electrically connected to the first bonding pads; a second chip structure on the solder resist layer, adjacent to the second side and electrically connected to the second bonding pads; a controller on the solder resist layer between the first chip structure and the second chip structure, and on the upper pads; and a connection structure passing through the passivation layer and the solder resist layer, and electrically connecting the controller and the upper pads.

According to example embodiments, a semiconductor package includes a substrate including edge pads, upper pads, and a passivation layer having openings exposing the edge pads; a solder resist layer on the passivation layer of the substrate and including open regions exposing the openings; at least one controller having an active surface and a non-active surface opposite to the active surface, the active surface facing an upper surface of the solder resist layer; a plurality of connection structures disposed between the at least one controller and the upper pads of the substrate, and electrically connecting the active surface of the at least one controller and the upper pads of the substrate; and at least one pair of chip structures on the solder resist layer, spaced apart from each other with the at least one controller disposed between the at least one pair of chip structures, wherein the at least one pair of chip structures includes upper surface pads electrically connected to the edge pads.

According to example embodiments, a semiconductor package includes a substrate including edge pads and upper pads disposed on an upper portion; a first solder resist layer on the substrate and exposing the edge pads; a second solder resist layer on the first solder resist layer and having a step from the first solder resist layer; at least one controller on the second solder resist layer and including a plurality of connection pads disposed in a lower portion of the at least one controller; at least one pair of chip structures disposed on the second solder resist layer, spaced apart from each other with the at least one controller disposed between the at least one pair of chip structures, the at least one pair of chip structures including upper surface pads disposed on respective upper surfaces; a connection structure penetrating through the first solder resist layer and the second solder resist layer and electrically connecting the plurality of connection pads of the at least one controller and the upper pad of the substrate; and a bonding wire structure electrically connecting the upper surface pads of the at least one pair of respective chip structures and the edge pads of the substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of a semiconductor package according to an example embodiment;

FIG. 2 is a schematic cross-sectional view of a semiconductor package according to an example embodiment;

FIG. 3A and FIG. 3B are schematic partial enlarged views of a semiconductor package according to example embodiments;

FIG. 4 is a cross-sectional view illustrating a semiconductor package according to example embodiments;

FIGS. 5A to 5H are schematic cross-sectional views for explaining a method of manufacturing a semiconductor device according to example embodiments; and

FIGS. 6A to 6F are schematic cross-sectional views for explaining a method of manufacturing a semiconductor device according to example embodiments.

### DETAILED DESCRIPTION

The inventive concepts may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concepts.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements may be exaggerated for effective description of the technical contents.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concepts. The singular forms include the plural forms unless the context clearly indicates otherwise.

Hereinafter, example embodiments will be described with reference to the accompanying drawings. Unless otherwise specified, in this specification, terms such as “upper portion”, “upper surface”, “lower portion”, “lower surface”, “side”, “side surface” and the like are based on the drawings, and in reality, may vary depending on the direction in which components are disposed.

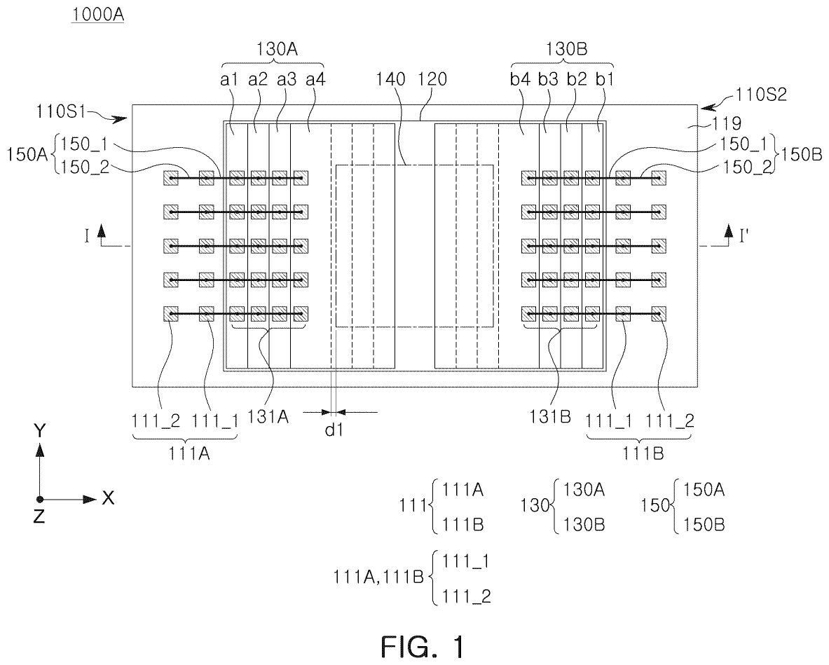

FIG. 1 is a schematic plan view of a semiconductor package 1000A according to an example embodiment.

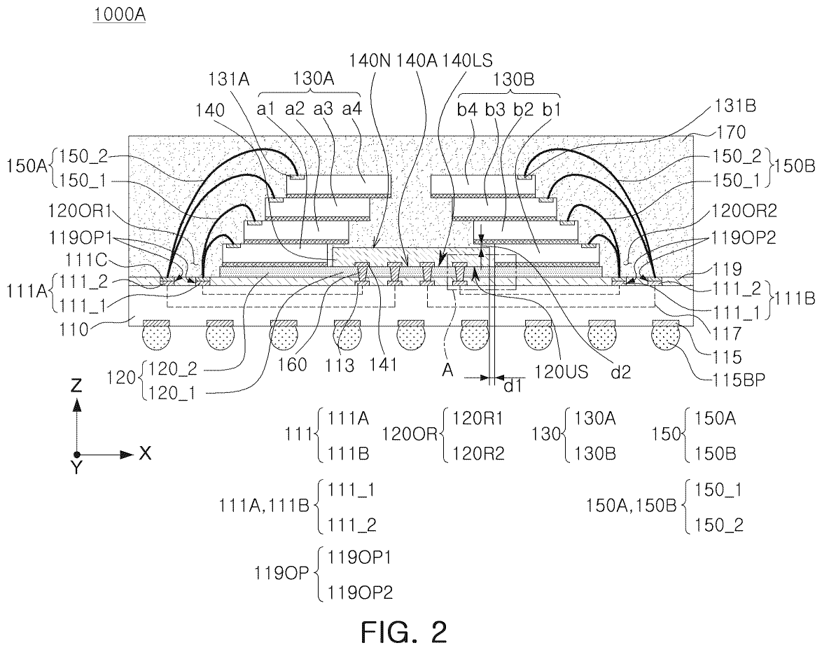

FIG. 2 is a schematic cross-sectional view of a semiconductor package 1000A according to an example embodiment. FIG. 2 illustrates a cross section along section line I-I′ in FIG. 1.

Referring to FIG. 1 and FIG. 2, the semiconductor package 1000A of an embodiment may include a substrate 110, a passivation layer 119 disposed on the substrate 110, a solder resist layer 120, a chip structure (130), a controller 140, a plurality of bonding wire structures 150, and a plurality of connection structures 160. In addition, the semiconductor package (1000A) may further include a encapsulant 170 on the substrate 110. The encapsulant 170 may seal the solder resist layer 120, the chip structure 130, and the controller 140 on the substrate 110. The encapsulant 170 may protect the chip structure 130 and the controller 140 from external environments such as physical shock or moisture. The encapsulant 170 may be formed, for example, by curing epoxy molding compound (EMC).

The present inventive concept may reduce a chip mounting area by arranging the controller 140 in the form of a flip-chip on the substrate 110 between different chips of the chip structure 130. A plurality of controllers, including the controller 140, may be disposed between the different chips of the chip structure 130. In addition, when the controller 140 is disposed on the substrate 110 using an underfill material, a defect may occur, such as a short circuit in the bonding wire structure 150 connecting the substrate 110 and the chip structure 130, due to fumes generated by curing the underfill material. The present inventive concept provides a solder resist layer 120 between the controller 140 and the substrate 110, and a short circuit in the bonding wire structure 150 may be prevented and the reliability of the semiconductor package (1000A) may be improved. The solder resist layer 120 between the controller 140 and the substrate 110 may not need to be hardened.

Hereinafter, each component of the semiconductor package 1000A will be described in detail.

The substrate 110 may be a substrate for a semiconductor package including a printed circuit board (PCB), a ceramic substrate, a glass substrate, or a tape wiring substrate. For example, the substrate 110 may be a double-sided printed circuit board (double-sided PCB) or a multilayer printed circuit board (multilayer PCB).

The substrate 110 may have a first side (11051) and a second side (11052) opposing each other in a first direction, for example the X-direction. The substrate 110 may include bonding pads 111 and upper pads 113 disposed at an upper surface of the substrate 110, bump pads 115 disposed at a bottom surface of the substrate 110, and a wiring circuit 117 electrically connecting the pads. The bump pads 115 may be disposed in the bottom surface of the substrate 110. The bonding pads 111, upper pads 113, and bump pads 115 may include at least one metal or an alloy composed of two or more metals among copper (Cu), aluminum (Al), nickel (Ni), silver (Ag), gold (Au), platinum (Pt), tin (Sn), lead (Pb), titanium (Ti), chromium (Cr), Palladium (Pd), indium (In), zinc (Zn), or carbon (C). Connection bumps 115BP may be disposed below the bump pads 115. The connection bumps 115BP may be electrically connected to the bump pads 115. The connection bumps 115BP may include, for example, tin (Sn) or an alloy containing tin (Sn) (e.g., Sn—Ag—Cu). The connection bumps 115BP may be electrically connected to external devices such as a module board and system board.

The chip structure 130 may include at least one pair of chip structures. For example, the chip structure 130 may include a first chip structure 130A and a second chip structure 130B. The first chip structure 130A and the second chip structure 130B may be a pair of chip structures. The first chip structure 130A and the second chip structure 130B may be spaced apart in the first direction (X-direction). For example, the controller 140 may be disposed between the first chip structure 130A and the second chip structure 130B of the chip structure 130. The first chip structure 130A may be adjacent to the first side (1101S) of the substrate 110 and second bonding pads 111B adjacent to the second side (110S2) of the substrate 110.

The bonding pads 111 (or ‘edge pads’) may be adjacent to the first side (1101S) and the second side (110S2) (or ‘edges’) of the substrate 110. The bonding pads 111 may be spaced apart in the first direction (X-direction), and may be arranged in a second direction perpendicular to the first direction, for example, the Y-direction. The bonding pads 111 may include first bonding pads 111A adjacent to the first side (110S1) of the substrate 110 and second bonding pads 111B adjacent to the second side (110S2) of the substrate 110. The first bonding pads 111A and the second bonding pads 111B may be spaced apart in the first direction (X-direction) and arranged in the second direction (Y-direction). For example, the first bonding pads 111A may be arranged in the second direction (Y-direction) between the first side 110S1 and the first chip structure 130A, and the second bonding pads 111B may be arranged in a second direction (Y-direction) between the second side 110S2 and the second chip structure 130B. The first bonding pads 111A and the second bonding pads 111B may each be electrically connected to the upper pad 113 through the wiring circuit 116 of the substrate 110.

Each of the first bonding pads 111A and the second bonding pads 111B may include first bonding fingers 111_1 and second bonding fingers 111_2. The first bonding fingers 111_1 and the second bonding fingers 1112 may be disposed between an end of the substrate 110 and the chip structure 130.

For example, the first bonding fingers 111_1 are disposed adjacent to the chip structure 130, and the second bonding fingers 111_2 may be disposed between the first bonding fingers 111_1 and the first side 110S1, and between the first bonding fingers 111_1 and the second side 11052. The first bonding fingers 111_1 and the second bonding fingers 111_2 may be connected to the lower semiconductor chips a1, a2, b1, and b2 and the upper semiconductor chips a3, a4, b3, and b4 through the lower wire 150_1 and the upper wire 1502, respectively. The first bonding fingers 111_1 and the second bonding fingers 111_2 may be electrically insulated from each other. In this manner, the first bonding fingers 111_1 and the second bonding fingers 111_2 are each connected to the connection pads 141 of the controller 140, and the controller 140 may provide and/or receive signals to/from the lower semiconductor chips (a1, a2, b1, b2) and the upper semiconductor chips (a3, a4, b3, b4) separately.

A metal pad 111C may be disposed on the bonding pads 111. The metal pad 111C may be formed on the bonding pads 111 through electrolytic plating or electroless plating. The metal pad 111C may include nickel (Ni), gold (Au), or a combination thereof.

The upper pads 113 may be disposed between the first bonding pads 111A and the second bonding pads 111B. The upper pads 113 may be electrically connected to the connection pads 141 disposed below the controller 140 through the connection structure 160. At least some of the upper pads 113 may be electrically connected to the first bonding pads 111A through the wiring circuit 116, and the remaining portions of the upper pads 113 may be electrically connected to the second bonding pads 111B through the wiring circuit 116. Although not illustrated, at least some of the upper pads 113 may be electrically connected to the bump pads 115 disposed on the lower portion of the substrate 110 through the wiring circuit 116.

The substrate 110 may further include a passivation layer 119 disposed at the top and bottom (not illustrated). The passivation layer 119 disposed on the upper portion may protect the bonding pads 111 and upper pads 113 disposed on the upper portion of the substrate 110 and the bump pads 115 disposed on the lower portion. The passivation layer 119 disposed on the top may include openings 1190P that open the upper surfaces of the bonding pads 111. The openings (1190P) may include first openings 1190P1 opening the upper surfaces of the first bonding pads 111A adjacent to the first side 11051, and second openings 1190P2 opening the upper surfaces of the second bonding pads 111B adjacent to the second side 11052.

The passivation layer 119 may include a solder resist containing epoxy resin or polyurethane resin, but is not limited thereto. For example, the passivation layer 119 may include a photosensitive solder resist (PSR) containing a photosensitive resin composition. In this case, the passivation layer 119 may be called a solder mask layer (or ‘first solder resist layer’). The passivation layer 119 may be formed using a screen printing method, a roll coating technique, a curtain cotton technique, and a spray technique, but is not limited thereto. For example, if the solder resist is a dry film, the passivation layer 119 may be formed using a film lamination technique.

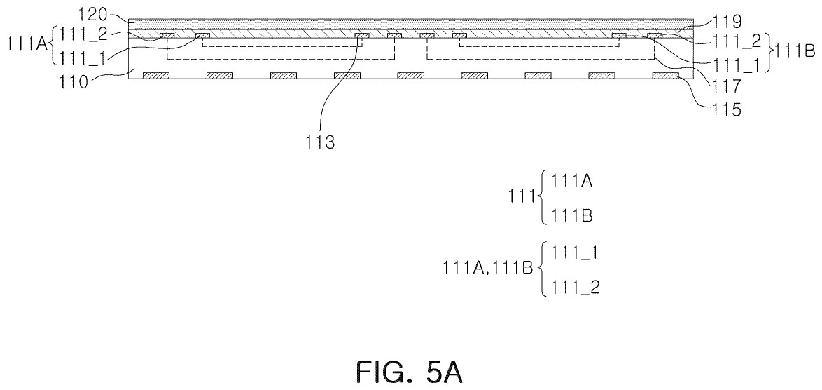

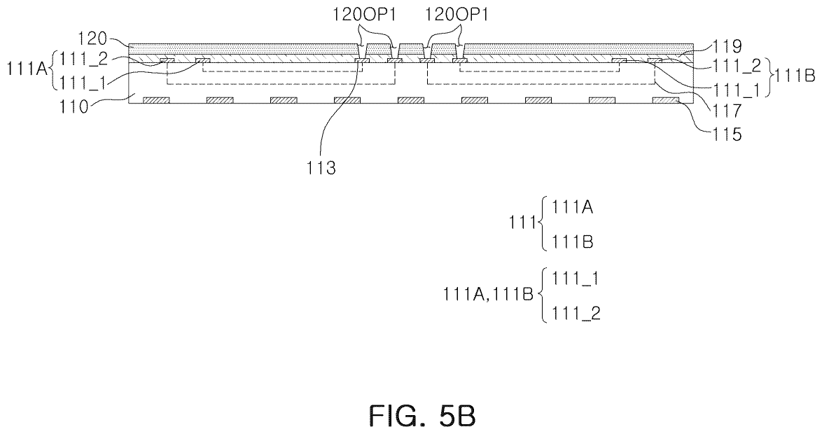

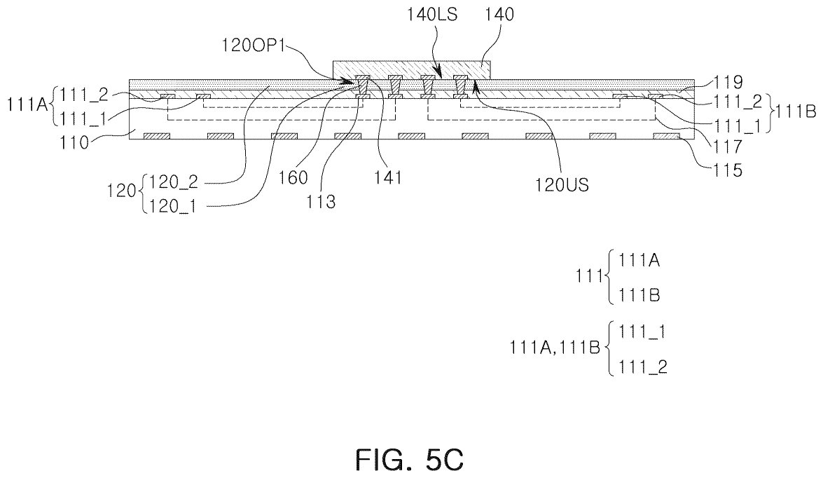

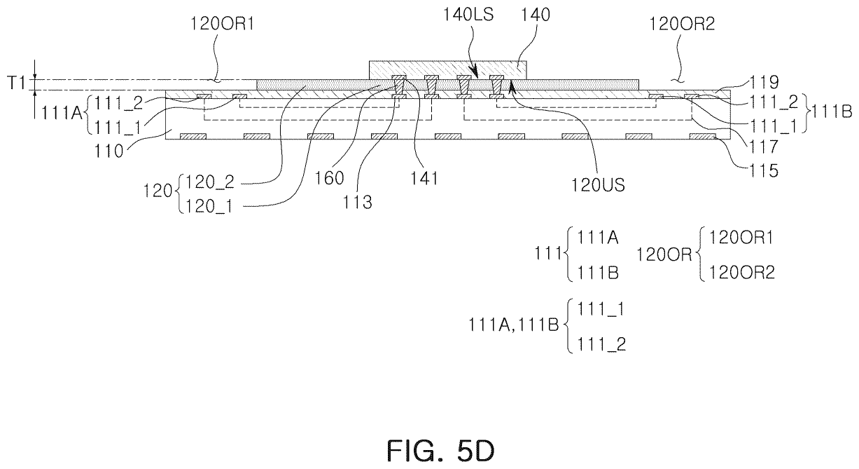

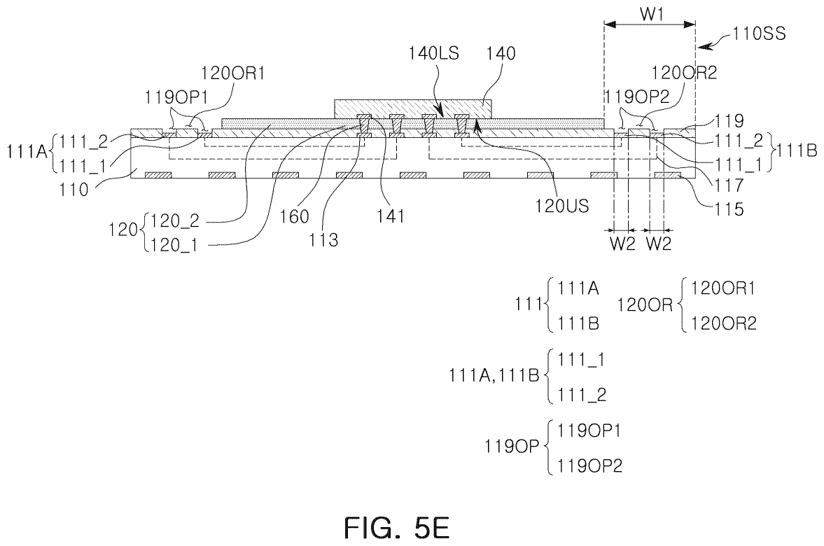

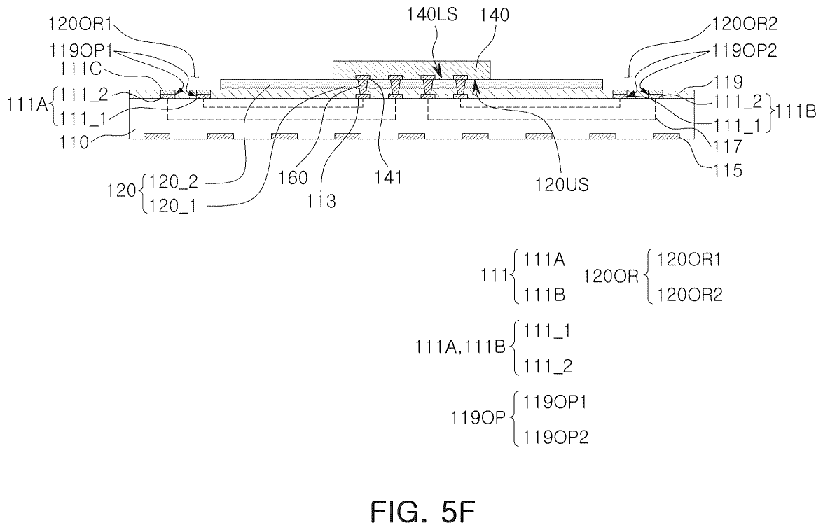

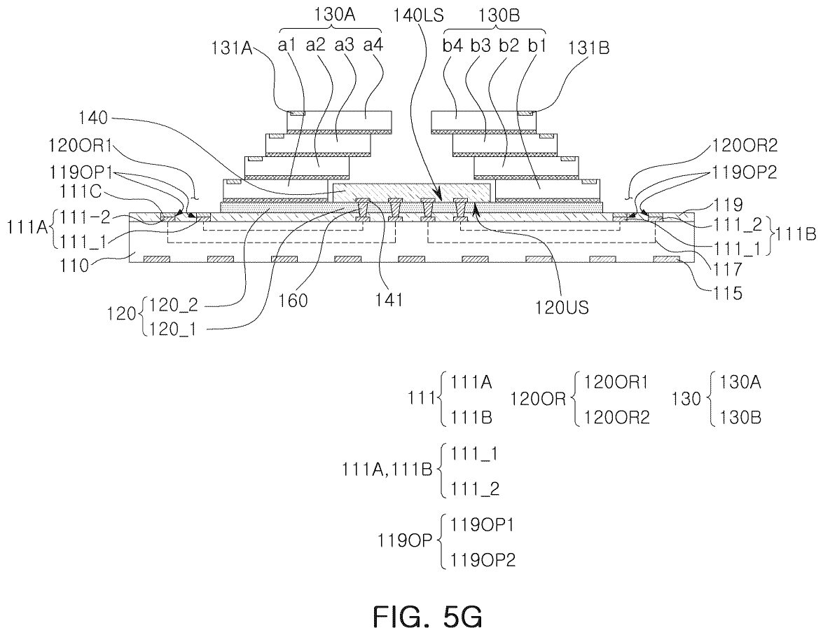

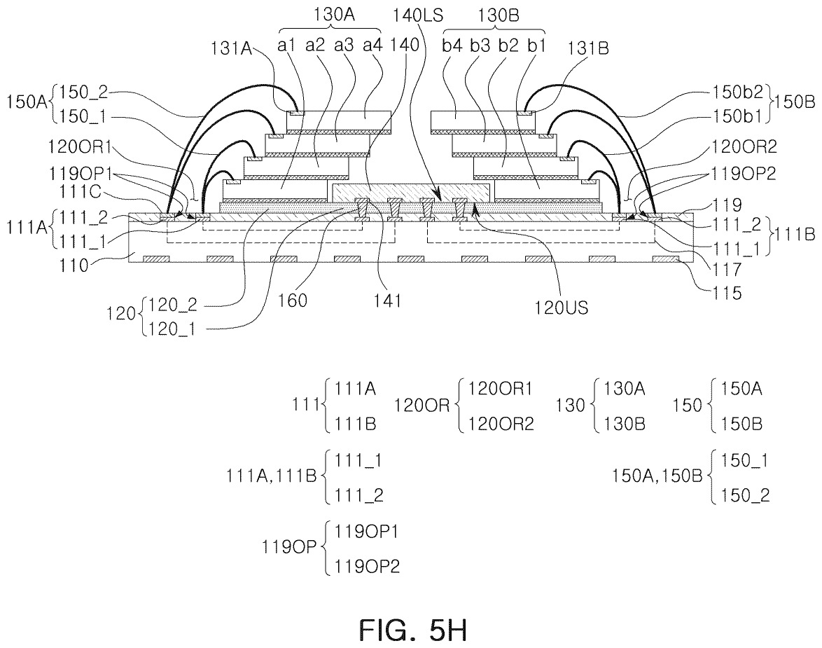

The solder resist layer 120 may be disposed on the passivation layer 119 and may be disposed to expose the openings 1190P in a third direction, for example, the Z-direction. The solder resist layer 120 may include open regions 1200R exposing the first openings 1190P1 and the second openings 1190P2. The open regions 1200R may include first open regions 1200R1 exposing first openings 1190P1 adjacent to the first side 110S1, and second open regions 1200R2 exposing second openings 1190P2 adjacent to the second side 11052. For example, the open regions 1200R may be formed to surround the solder resist layer 120 on the substrate 110 (or ‘passivation layer 119’). In this case, the first width W1 of the open regions 1200R in the first direction (X-direction) may be defined as the distance in the first direction (X-direction) from the side surface of the solder resist layer 120 to the virtual surface 110SS extending from the side of the end of the substrate 110 (or ‘passivation layer 119’) in the second direction (Y-direction) (see FIG. 5E). To more precisely place the bonding wire structure 150 on the first bonding pads 111A and second bonding pads 111B disposed within the openings 1190P (see FIG. 5H), the first width W1 of the open regions 1200R may have a greater horizontal width than the second width W2 in the first direction (X-direction) of the openings 1190P (see FIG. 5E).

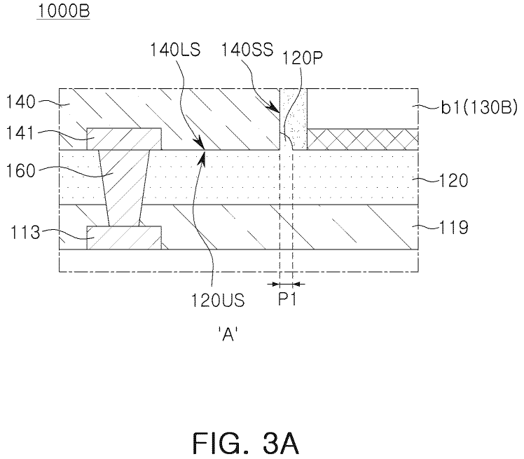

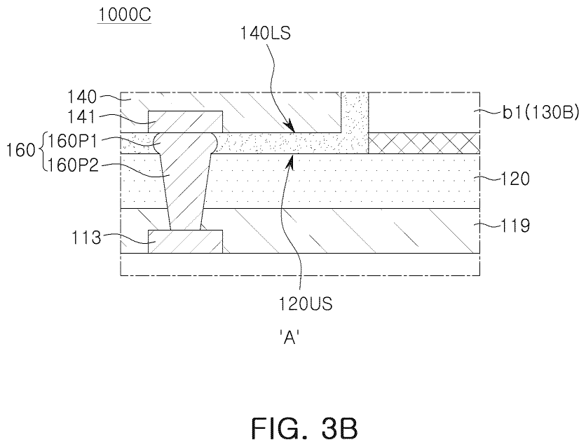

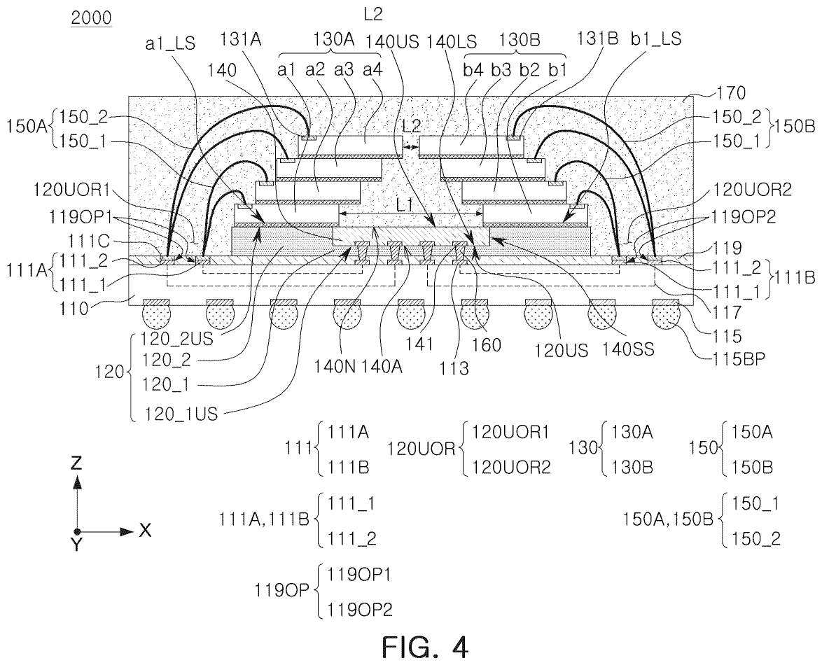

A controller 140 and the first chip structure 130A and the second chip structure 130B of the chip structure 130 spaced apart in a first direction (X-direction) may be disposed on the solder resist layer 120 with the controller 140 at a center portion. The solder resist layer 120 may include a first portion 120_1 interposed between the substrate 110 and the controller 140 and a second portion 1202 disposed between the substrate 110 and the chip structure 130. The solder resist layer 120 may have a planar structure such that the upper surfaces of the first portion 120_1 and the second portion 120_2 are substantially at the same level, but is not limited thereto. In an example embodiment, the upper surface 120_2US of the second portion 120_2 of the solder resist layer 120 may be at a higher level than the upper surface 120_1US of the first portion 120_1 (see FIG. 4). The upper surface 120US of the solder resist layer may contact the lower surface 140LS of the controller 140. However, in an example embodiment, the upper surface 120US of the solder resist layer and the lower surface 140LS of the controller 140 may be arranged to be spaced apart from each other (see FIG. 3B).

The solder resist layer 120 may use a photosensitive solder resist (PSR) containing a photosensitive resin composition. In this case, the solder resist layer 120 may be called a photosensitive solder resist layer (or ‘second solder resist layer’). The solder resist layer 120 may be formed using a screen printing method, a roll coating technique, a curtain cotton technique, and a spray technique, but is not limited thereto. For example, if the photosensitive solder resist is a dry film, the solder resist layer 120 may be formed using a film lamination technique.

The first chip structure 130A and the second chip structure 130B of chip structure 130 may be arranged to be spaced apart in a first direction (X-direction) on the solder resist layer 120, and may include a plurality of semiconductor chips with pads disposed on each upper surface. For example, the first chip structure 130A may be disposed on the solder resist layer 120 adjacent to the first side 11051, and the second chip structure 130B may be disposed on the solder resist layer 120 adjacent to the second side 11052. The first chip structure 130A may include a plurality of first semiconductor chips a1, a2, a3, and a4, each of which has first pads 131A disposed on its upper surface, and the second chip structure 130B may include a plurality of second semiconductor chips b1, b2, b3, and b4, each of which has second pads 131B disposed on its upper surface. A plurality of semiconductor chips may be attached to each other by, for example, an adhesive film (e.g., DAF).

The plurality of first semiconductor chips a1, a2, a3, and a4 may be stacked. The plurality of first semiconductor chips a1, a2, a3, and a4 may be stacked and sequentially offset in the first direction (X-direction) such that the first pads 131A may be adjacent to the first side 11051. The plurality of first semiconductor chips a1, a2, a3, and a4 may be stacked and sequentially offset in the first direction (X-direction) such that the first pads 131A adjacent to the first side 110S1 may be exposed at top surfaces of the plurality of first semiconductor chips a1, a2, a3, and a4.

The plurality of second semiconductor chips b1, b2, b3, and b4 may be stacked. The plurality of second semiconductor chips b1, b2, b3, and b4 may be stacked and sequentially offset opposite to the first direction (X-direction) such that the second pads 131B may be adjacent to the second side 11052. The plurality of second semiconductor chips b1, b2, b3, and b4 may be stacked and sequentially offset opposite to the first direction (X-direction) such that the second pads 131B adjacent to the second side 11052 may be exposed at top surfaces of the plurality of second semiconductor chips b1, b2, b3, and b4.

The plurality of first semiconductor chips (a1, a2, a3, a4) may be disposed adjacent to the plurality of second semiconductor chips (b1, b2, b3, b4), respectively. The plurality of first semiconductor chips (a1, a2, a3, a4) may be stacked and sequentially offset in the first direction (X-direction) and the plurality of second semiconductor chips (b1, b2, b3, b4) may be stacked and sequentially offset opposite to the first direction (X-direction), and upper ones of the plurality of first semiconductor chips (a1, a2, a3, a4) and the plurality of second semiconductor chips (b1, b2, b3, b4) disposed at a same level may be closer to one another in the first direction (X-direction) than lower ones of the plurality of first semiconductor chips (a1, a2, a3, a4) and the plurality of second semiconductor chips (b1, b2, b3, b4) disposed at a same level. For example, highest chips (e.g., first semiconductor chip a4 and second semiconductor chip b4) among the plurality of first semiconductor chips (a1, a2, a3, a4) and the plurality of second semiconductor chips (b1, b2, b3, b4) may be closer to one another in the first direction (X-direction) than over chips disposed at a same level.

A controller 140 may control a plurality of first semiconductor chips (a1, a2, a3, a4) and a plurality of second semiconductor chips (b1, b2, b3, b4), and may be disposed between the first chip structure 120A and the second chip structure 120B. In detail, each of the first chip structure 130A and the second chip structure 130B may be disposed on the solder resist layer 120 with the controller 140 disposed at the center portion and spaced apart by a predetermined distance in the first direction (X-direction). For example, the first semiconductor chip (a1) at the lowest level among the plurality of first semiconductor chips (a1, a2, a3, a4) may be disposed on the solder resist layer 120 adjacent to the first side 110s1 of the substrate 110 and spaced apart from the controller 140 by a first distance d1 in the first direction (X-direction), and the second semiconductor chip (b1) at the lowest level among the plurality of second semiconductor chips (b1, b2, b3, b4) may be disposed on the solder resist layer 120 adjacent to the second side 11052 of the substrate 110 and spaced apart from the controller 140 by a first distance d1 in the first direction (X-direction). The first distance d1 may be about 50 um or more, for example, 50 um to 150 um, 50 um to 100 um, 50 um to 80 um, or 50 um to 60 um. As illustrated in FIG. 1, some of the plurality of first semiconductor chips (e.g., a2, a3, a4) and some of the plurality of second semiconductor chips (e.g., b2, b3, b4) may overlap at least a portion of the non-active surface 140N of the controller 140. In addition, the semiconductor chips (a2, b2) disposed on the upper surfaces of the first and second semiconductor chips (a1, b1) at the lowest level may be arranged to be spaced apart from the upper surface of the controller 140 by a second distance d2 in the third direction (Z-direction). For example, the first direction may be a substantially horizontal direction and the third direction may be a substantially vertical direction. The second distance d2 may be substantially the same size as the first distance d1 or may be larger than the first distance d1. The second spacing d2 may be about 50 um or more, for example, 50 um to 200 um, 50 um to 150 um, 80 um to 150 um, or 80 um to 100 um.

A plurality of first semiconductor chips (a1, a2, a3, a4) and a plurality of second semiconductor chips (b1, b2, b3, b4) may include non-volatile memory semiconductor chips such as flash memory, phase-change random access memory (PRAM), magnetoresistive random access memory (MRAM), ferroelectric random access memory (FeRAM), or resistive random access memory (RRAM), and/or volatile memory semiconductor chips, such as Dynamic Random Access Memory (DRAM) or Static Random Access Memory (SRAM).

At least one controller 140 may be disposed between the first chip structure 130A and the second chip structure 130B of the chip structure 130 spaced apart in a first direction (X-direction). At least one controller 140 may have an active surface 140A on which connection pads 141 are disposed, and a non-active surface (140N) on the opposite side of the active surface. The active surface (140A) may be disposed to face the upper surface (120US) of the solder resist layer. The connection pads 141 of the at least one controller 140 may be electrically connected to the upper pad 113 of the substrate 110 by the connection structure 160 disposed to penetrate the passivation layer 119 and the solder resist layer 120. At least one controller 140 may be electrically connected to the chip structure 130 through the connection structure 160, the wiring circuit 117, and the bonding wire structure 150.

The bonding wire structures 150 may include a first bonding wire structure 150A connecting the first pads 131A of the first chip structure 130A to the first bonding pads 111A, and a second bonding wire structure 150B connecting the second pads 131B of the second chip structure 130B to the second bonding pads 111B.

The first bonding wire structure 150A may extend from the first chip structure 130A toward the first side 11051. The second bonding wire structure 150B may extend from the second chip structure 130B toward the second side 11052. The first bonding wire structure 150A and the second bonding wire structure 150B may be electrically connected to the wiring circuit 117 of the substrate 110.

Each of the first bonding wire structure 150A and the second bonding wire structure 150B may include a lower wire (150_1) connecting the first bonding fingers (111_1) and some lower semiconductor chips (e.g., a1, a2, b1, b2) among the plurality of first semiconductor chips (a1, a2, a3, a4) and the plurality of second semiconductor chips (b1, b2, b3, b4), and an upper wire (150_2) connecting the second bonding fingers (111_2) and remaining upper semiconductor chips (e.g., a3, a4, b3, b4) among the plurality of first semiconductor chips (a1, a2, a3, a4) and the plurality of second semiconductor chips (b1, b2, b3, b4). The lower wire 150_1 and the upper wire 150_2 may be electrically insulated. Accordingly, the controller 140 may provide and/or receive signals to/from the lower semiconductor chips (a1, a2, b1, b2) and the upper semiconductor chips (a3, a4, b3, b4) separately.

The connection structure 160 (or ‘solder structure’) may be disposed within the solder resist layer 120 and the passivation layer 119. The upper surface 120US of the solder resist layer 120 may be formed to have a shape that is tapered as it moves away from the upper surface 120US (e.g., opposite to the third direction (Z-direction)). For example, the connection structure 160 may penetrate through the solder resist layer 120 and the passivation layer 119, connect the connection pad 141 of the controller 140 and the upper pad 113 of the substrate 110, and may be disposed such that the horizontal width gradually decreases in a direction vertically moving away from the controller 140 (or the ‘controller connection pad 141’). Stated another way, the horizontal width gradually decreases as a distance from the controller 140 (or the ‘controller connection pad 141’) increases within the passivation layer 119 and the solder resist layer 120. The connection structure 160 may include the same or similar material as the connection bumps 115BP, but is not limited thereto. For example, the connection structure 160 may include tin (Sn) or an alloy containing tin (Sn) (e.g., Sn—Ag—Cu).

FIG. 3A is a schematic partially enlarged view of a semiconductor package 1000B according to example embodiments.

Referring to FIG. 3A, the semiconductor package 1000B of an embodiment may have the same or similar features as those described with reference to FIG. 1 and FIG. 2, and the solder resist layer 120 may have a protrusion 120P protruding from the upper surface 120US of the solder resist layer. For example, the protrusion 120P may protrude from the upper surface 120US of the solder resist layer 120 and contact at least a portion of the side surface 140SS of the controller 140. Referring to FIG. 3A and FIG. 5C, in a process of pressing the controller 140 such that the lower surface (140LS) of the controller and the upper surface (120US) of the solder resist layer 120 contact each other, the protrusion 120P may protrude from the upper surface of the solder resist layer 120. The width P1 of the protrusion 120P in the first direction (X-direction) may be about 50 um or less, for example, 10 um to 50 um, 10 um to 40 um, or 20 um to 30 um.

FIG. 3B is a schematic partial enlarged view of a semiconductor package 1000C according to example embodiments.

Referring to FIG. 3B, the semiconductor package 1000C of an embodiment may have the same or similar features as those described with reference to FIG. 1 and FIG. 2, and the controller 140 and the solder resist layer 120 may be spaced apart. For example, the lower surface 140LS of the controller 140 and the upper surface 120US of the solder resist layer 120 may be arranged to be spaced apart from each other in the third direction (Z-direction). The connection structure 160 may include a first structure (160P1) disposed between the lower surface (140LS) of the controller 140 and the upper surface (120US) of the solder resist layer, and a second structure 160P2 penetrating through the solder resist layer 120 and the passivation layer 119. The first structure 160P1 may be in contact with the connection pad 141 of the controller 140 and may have a convex shape in the horizontal direction (e.g., X-direction) on the upper surface 120US of the solder resist layer. For example, the first structure 160P1 may a convex shape in the horizontal direction around an entire periphery thereof. The second structure 160P2 may extend from the lower portion of the first structure 160P1 at the upper surface 120US of the solder resist layer, and may be arranged to have a shape tapering in a direction vertically away from the upper surface 120US of the solder resist layer. The second structure 160P2 may contact the upper pad 113 of the substrate 110.

FIG. 4 is a cross-sectional view illustrating a semiconductor package 2000 according to example embodiments.

Referring to FIG. 4, the same or similar features as those described with reference to FIG. 1 and FIG. 2 may be provided, and the second portion 120_2 of the solder resist layer 120 may extend in the third direction (Z-direction) and may be disposed at a higher level than the first portion 120_1.

For example, the second portion 1202 may be at substantially the same level as the controller 140. The solder resist layer 120 may have open regions 120UOR having a greater depth than the depth in the third direction (Z-direction) of the open regions 1200R described with reference to FIG. 1. Accordingly, the second portion 120_2 may contact the side surface 140SS of the controller, but is not limited thereto. For example, the second portion 1202 may be disposed at a predetermined distance from the side surface 140SS of the controller.

In an embodiment, at least portions of the lower surfaces of the first and second semiconductor chips located at the lowest level of the plurality of respective first semiconductor chips (a1, a2, a3, a4) and the plurality of respective second semiconductor chips (b1, b2, b3, b4). At least some of (a1_LS, b1_LS) may be disposed on the upper surface (120_2US) of the second portion, and the remaining part of the lower surfaces (a1_LS, b1_LS) of the first and second semiconductor chips at the lowest level may be disposed on the upper surface (140US) of the controller. Accordingly, the first chip structure 130A and the second chip structure 130B may be disposed such that at least one pair of chip structures 130 described with reference to FIG. 1 are spaced apart by a smaller distance than the distance in the first direction (X). For example, the first and second semiconductor chips (a1, b1) may be arranged to be spaced apart by a first distance (L1) in the first direction (X), and the first and second semiconductor chips (a4, b4) at the top may be arranged to be spaced apart by a second distance (L2) in the first direction (X). In this case, the first distance L1 may be about 300 um or more, for example, 300 um to 750 um, 350 um to 750 um, or 400 um to 600 um. The second distance (L2) may be about 80 um or more, for example, 80 um to 200 um, 100 um to 200 um, or 100 um to 150 um. As illustrated in FIG. 4, the plurality of respective first semiconductor chips (a1, a2, a3, a4) and the plurality of respective second semiconductor chips (b1, b2, b3, b4) may overlap at least a portion of the upper surface 140US of the controller 140.

Although not illustrated, the upper surface 120_2US of the second portion may be located at a higher level than the upper surface 140US of the controller. For example, the controller 140 may be disposed inside the solder resist layer 120. In this case, at least some of the lower surfaces (a1_LS, b1_LS) of the first and second semiconductor chips at the lowest level may be disposed at a predetermined distance from the upper surface (140US) of the controller.

FIGS. 5A to 5H are schematic cross-sectional views for explaining a method of manufacturing a semiconductor device according to example embodiments. FIGS. 5A to 5H illustrate a manufacturing method for a cross section of the semiconductor package 1000A illustrated in FIG. 2.

Referring to FIG. 5A, a passivation layer 119 may be formed on the substrate 110, and a solder resist layer 120 may be formed on the passivation layer 119.

The passivation layer 119 may be formed on the substrate 110 to cover the bonding pads 111 and upper pads 113 disposed on the top of the substrate 110.

The passivation layer 119 may be formed using a first solder resist. The first solder resist may be applied to the substrate 100 by a screen printing method. The first solder resist may be a solder resist containing epoxy resin or polyurethane resin. Depending on an example embodiment, the first solder resist may include a photosensitive resin.

The solder resist layer 120 may be formed on the passivation layer 119 to cover the upper surface of the passivation layer 119. The solder resist layer 120 may be formed having a step from the passivation layer 119. For example, a width and/or a length of the solder resist layer 120 may be less than that of the passivation layer 119.

The solder resist layer 120 may be formed using a second solder resist. The second solder resist may be a photosensitive solder resist containing a photosensitive resin composition, and may be in the form of a liquid or a dry film. If the second solder resist is liquid, it may be applied on the passivation layer 119 by screen printing. If the second solder resist is a film, it may be formed on the passivation layer 119 by a film lamination technique.

Referring to FIG. 5B, first open portions 1200P1 that penetrate the solder resist layer 120 and the passivation layer 119 and expose the upper surfaces of the upper pads 113 of the substrate 110 may be formed. The first open portions 1200P1 may be formed through a photolithography process.

Referring to FIG. 5C, the connection structure 160 may be disposed on the solder resist layer 120, and the controller 140 attached to the lower surface of the connection pad 141 is arranged such that the connection structure 160 is disposed in the first open portions 1200P1. The controller 140 may be pressed such that the lower surface 140LS of the controller 140 and the upper surface 120US of the solder resist layer contact each other, and as illustrated in FIG. 3A, by squeezing the controller 140, at least a portion of the solder resist layer 120 may protrude from the upper surface of the solder resist layer 120 to form a protrusion 120P that contacts at least a portion of the side surface of the controller 140.

Referring to FIG. 5D, on the solder resist layer 120, a first open region 1200R1 may be formed on the first side 110s1 of the substrate 110 and a second open region 1200R2 is formed on the second side 11052. The first open region 1200R1 and the second open region 1200R2 may be formed such that the passivation layer 119 disposed on the first bonding pads 111A and the second bonding pads 111B is exposed in the first direction (X-direction). The first width W1 in the first direction (X-direction) of the open regions 1200R may be formed to have a horizontal width greater than the second width W2 in the first direction (X-direction) of the openings 1190P. The first open region 1200R1 and the second open region 1200R2 may be formed through, for example, a photolithography process.

Referring to FIG. 5E, on the passivation layer 119, a first opening 1190P1 may be formed on the first side 11051 of the substrate 110 and a second opening 1190P2 may be formed on the second side 11052. The first opening 1190P1 and the second opening 1190P2 may be formed to expose the upper surfaces of the first bonding pads 111A and the upper surfaces of the second bonding pads 111B. The first opening 1190P1 and the second opening 1190P2 may be formed through, for example, a photolithography process.

Referring to FIG. 5F, on the surfaces of the first bonding pads 111A and the second bonding pads 111B disposed in the openings 1190P. A metal pad 111C containing nickel (Ni), gold (Au), or a combination thereof may be formed. The metal pad 111C may be formed through, for example, electrolytic plating or electroless plating.

Referring to FIG. 5G, a first chip structure 130A and a second chip structure 130B may be disposed on sides of the controller 140 on the solder resist layer 120. For example, the first chip structure 130A and the second chip structure 130B may be disposed on opposite sides of the controller 140 on the solder resist layer 120. The first chip structure 130A and the second chip structure 130B may be attached to the upper surface 120US of the solder resist layer 120 by an adhesive film attached to the lower portion. The first chip structure 130A may include a plurality of first semiconductor chips a1, a2, a3, and a4, each of which has first pads 131A disposed on its upper surface, and the second chip structure 130B may include a plurality of second semiconductor chips b1, b2, b3, and b4, each of which has second pads 131B disposed on the upper surface thereof. A plurality of first semiconductor chips a1, a2, a3 and a4 may be stacked and sequentially offset, such that the first pads 131A may be adjacent to the first side 11051, and a plurality of second semiconductor chips b1, b2, b3, and b4 may be stacked and sequentially offset such that the second pads 131B may be adjacent to the second side 11052.

Referring to FIG. 5H, a first bonding wire structure 150A connecting the first pads 131A to the first bonding pad 111A, and a second bonding wire structure 150B connecting the second bonding pads 111B to the second bonding pad 111B may be formed. Each of the first bonding wire structure 150A and the second bonding wire structure 150B may include a lower wire 150_1 connecting the lower semiconductor chips a1, a2, b1, and b2 to the first bonding fingers 111_1, and an upper wire (150_2) connecting the upper semiconductor chips (a3, a4, b3, b4) to the second bonding fingers (111_2). The lower wire 150_1 and the upper wire 150_2 may be electrically insulated. The controller 140 may provide and/or receive signals to/from the lower semiconductor chips a1, a2, b1, and b2 and the upper semiconductor chips a3, a4, b3, and b4. The encapsulant (‘170’ in FIG. 2) may be formed on the first bonding wire structure 150A and the second bonding wire structure 150B. The connecting bumps (‘115BP’ in FIG. 2) may be formed before or after the first bonding wire structure 150A and the second bonding wire structure 150B are formed.

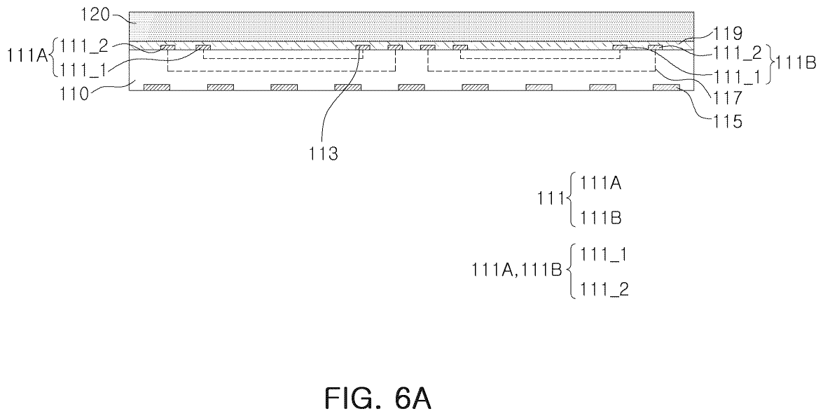

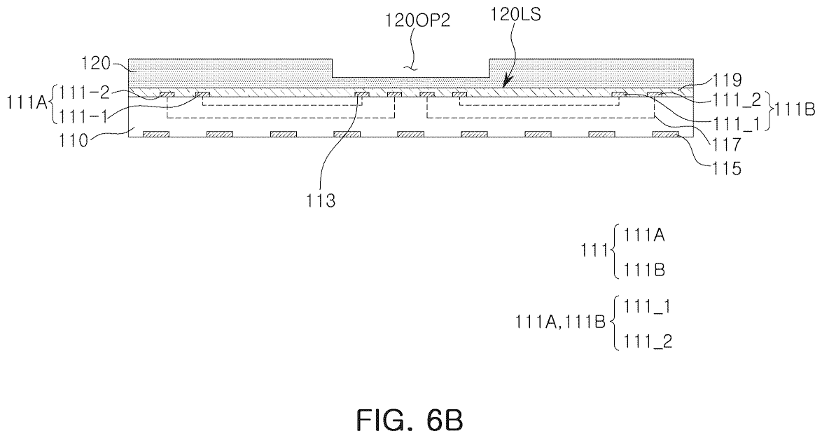

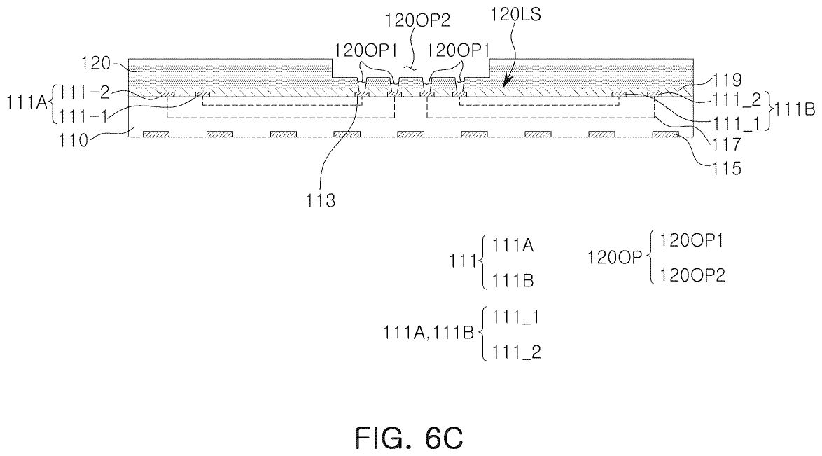

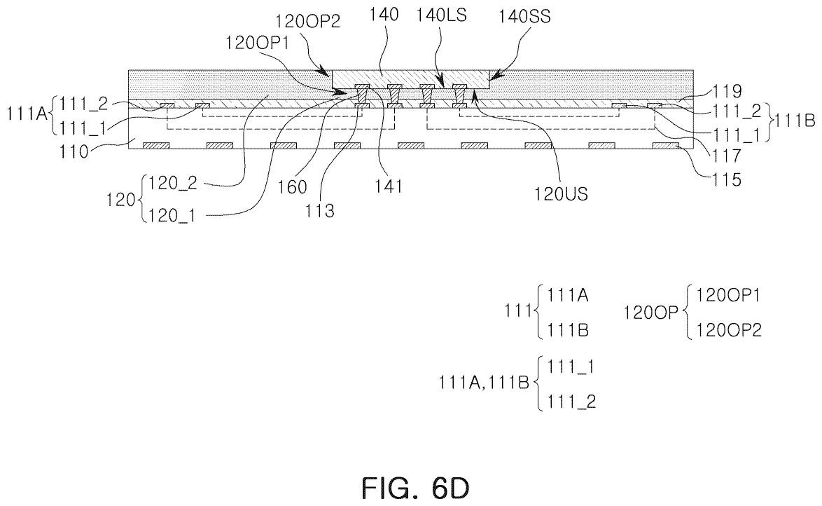

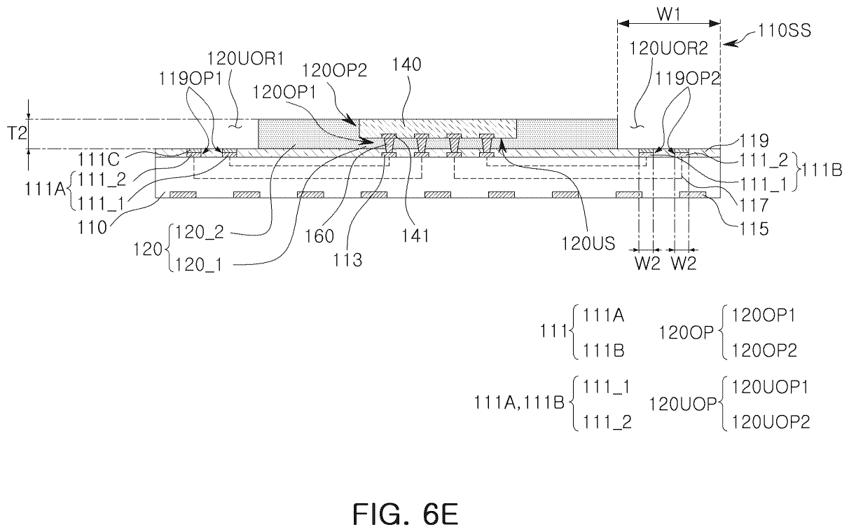

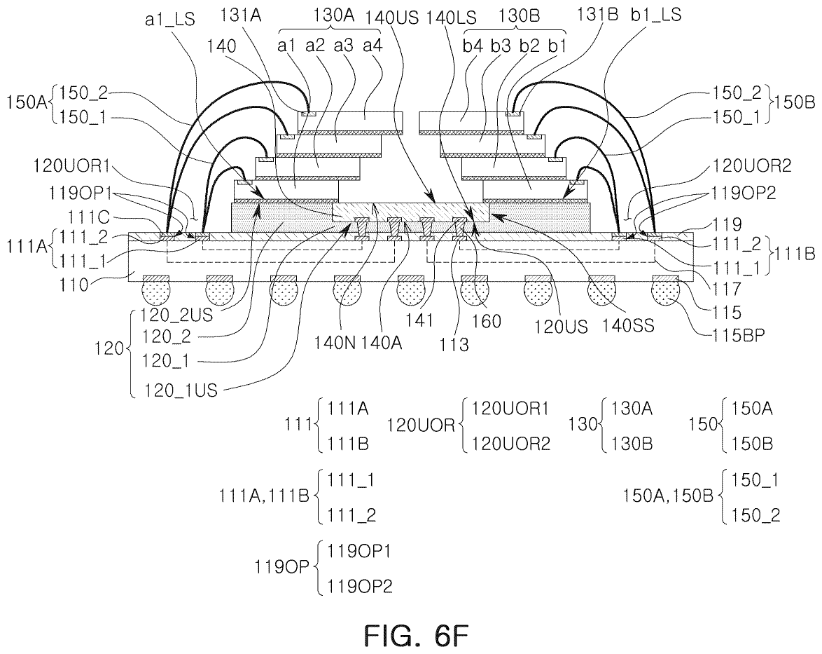

FIGS. 6A to 6F are schematic cross-sectional views for explaining a method of manufacturing a semiconductor device according to example embodiments. FIGS. 6A to 6F illustrate a manufacturing method for a cross section of the semiconductor package 2000 illustrated in FIG. 4.

Referring to FIG. 6A, similar to FIG. 5A, a passivation layer 119 may be formed on the substrate 110, and a solder resist layer 120 may be formed on the passivation layer 119. As illustrated in FIG. 6A, the solder resist layer 120 may be formed to be thicker than the thickness of the solder resist layer 120 illustrated in FIG. 5A.

Referring to FIG. 6B, a second open portion 1200P2 penetrating at least a portion of the solder resist layer 120 may be formed. The second open portion 1200P2 may be formed on the upper pad 113 of the substrate 110 such that the lower surface 120LS of the solder resist layer 120 may not be exposed. The depth of the second open portion 1200P2 may be equal to the thickness of the controller 140 disposed in the second open portion 1200P2. The second open portion 1200P2 may be formed through a photo lithography process, and the depth of the second open portion 1200P2 may be adjusted by adjusting the exposure time to light (e.g., UV) and/or the intensity of the exposed light.

Referring to FIG. 6C, similar to FIG. 5B, first open portions 1200P1 may be formed by penetrating the solder resist layer 120 and the passivation layer 119 exposed by the second open portion 1200P2 and to expose the upper surfaces of the upper pads 113 of the substrate 110. The first open portions 1200P1 may be formed through a photo lithography process.

Referring to FIG. 6D, the controller 140 in which the connection structure 160 is attached to the lower surface of the connection pad 141 may be disposed on the solder resist layer 120, such that the connection structure 160 may be disposed in the first open portions 1200P1 and the controller 140 may be disposed in the second open portions 1200P2. The controller 140 may be pressed such that the lower surface 140LS of the controller 140 and the upper surface 120US of the solder resist layer 120 contact each other, and the side surface 140SS of the controller 140 may be arranged to be surrounded by the solder resist layer 120 in the second open portion 1200P2. Accordingly, the controller 140 may be at the same level as the second portion 120-2 of the solder resist layer.

Referring to FIG. 6E, similar to FIG. 5D, on the solder resist layer 120, a first open area 1200R1 may be formed on the first side 110S1 of the substrate 110 and a second open region 1200R2 may be formed on the second side 11052. As illustrated in FIG. 6E, the depth T2 of the first open region 1200R1 and the second open region 1200R2 in the third direction (Z-direction) may be greater than the depth T1 of the first open region 1200R1 and the second open region 1200R2 illustrated in FIG. 5D in the third direction (Z-direction).

Similar to FIG. 5E, on the passivation layer 119, a first opening 1190P1 may be formed on the first side 110s1 of the substrate 110 and a second opening 1190P2 may be formed on the second side 11052. Similar to FIG. 5F, a metal pad 111C including nickel (Ni), gold (Au), or a combination thereof may be formed on the surfaces of the first bonding pads 111A and the second bonding pads 111B disposed in the openings 1190P.

Referring to FIG. 6F, similar to FIG. 5G, the first chip structure 130A and the second chip structure 130B may be disposed on both sides of the controller 140 on the solder resist layer 120. The first chip structure 130A includes a plurality of first semiconductor chips a1, a2, a3, and a4, each of which has first pads 131A disposed on its upper surface, and the second chip structure 130B may include a plurality of second semiconductor chips b1, b2, b3, and b4, each of which has second pads 131B disposed on its upper surface. A plurality of first semiconductor chips (a1, a2, a3, a4) may be stacked and sequentially offset such that the first pads (131A) may be adjacent to the first side (11051), and a plurality of second semiconductor chips b1, b2, b3, and b4 may be stacked and sequentially offset such that the second pads 131B may be adjacent to the second side 11052.

At least portions of the lower surfaces (a1_LS, b1_LS) of the first semiconductor chip a1 disposed at the lowest position in the first chip structure 130A and the second semiconductor chip b1 disposed at the lowest position in the second chip structure 130B may be disposed on the non-active surface 140N of the controller. The first chip structure 130A and the second chip structure 130B may be attached to the upper surface 120US of the solder resist layer 120 and the non-active surface 140N of the controller 140 by an adhesive film attached to the lower portion.

Similar to FIG. 5H, a first bonding wire structure 150A connecting the first pads 131A to the first bonding pad 111A, and a second bonding wire structure 150B connecting the second bonding pads 111B to the second bonding pad 111B may be formed. The encapsulant (‘170’ in FIG. 2) may be formed on the first bonding wire structure 150A and the second bonding wire structure 150B. The connecting bumps (‘115BP’ in FIG. 2) may be formed before or after the first bonding wire structure 150A and the second bonding wire structure 150B are formed.

As set forth above, according to example embodiments, a semiconductor package having reduced size and improved reliability may be provided.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a substrate having a first side and a second side opposing each other;
a plurality of pads disposed on the substrate,
wherein the plurality of pads include first bonding pads arranged adjacent to the first side, second bonding pads arranged adjacent to the second side, and upper pads disposed between the first bonding pads and the second bonding pads;
a passivation layer disposed on the substrate,
wherein the passivation layer exposes the first bonding pads and the second bonding pads;
a solder resist layer disposed on the passivation layer of the substrate;
a first chip structure disposed on the solder resist layer adjacent to the first side and electrically connected to the first bonding pads;
a second chip structure disposed on the solder resist layer adjacent to the second side and electrically connected to the second bonding pads;
a controller disposed on the solder resist layer between the first chip structure and the second chip structure, the controller includes a plurality of connection pads in a lower portion of the controller; and
a connection structure penetrating the passivation layer and the solder resist layer, and electrically connecting the controller and the upper pads,
wherein at least a portion of the connection structure has a horizontal width decreasing as a distance from the controller increases within the passivation layer and the solder resist layer.

2. The semiconductor package of claim 1, wherein a lower surface of the controller is in contact with an upper surface of the solder resist layer.

3. The semiconductor package of claim 2, wherein the solder resist layer has a protrusion protruding from the upper surface of the solder resist layer and contacting at least a portion of a side surface of the controller.

4. The semiconductor package of claim 1, wherein a lower surface of the controller is spaced apart from an upper surface of the solder resist layer.

5. The semiconductor package of claim 1, wherein the connection structure includes,
a first structure convex in a first direction between a lower surface of the controller and an upper surface of the solder resist layer; and
a second structure extending from a lower surface of the first structure in a second direction perpendicular to the first direction,
wherein a width of the second structure in the first direction decreases as a distance from the lower surface of the first structure increases.

6. The semiconductor package of claim 1, wherein the solder resist layer includes a first portion interposed between the passivation layer and the controller, and a second portion disposed between the passivation layer and the first chip structure and between the passivation layer and the second chip structure, and
an upper surface of the second portion is at substantially a same level as an upper surface of the first portion or is at a higher level than the upper surface of the first portion.

7. The semiconductor package of claim 1, wherein the first chip structure includes a plurality of first semiconductor chips with first pads disposed on each upper surface, and
the second chip structure includes a plurality of second semiconductor chips with second pads disposed on each upper surface,
wherein the plurality of first semiconductor chips are stacked and sequentially offset in a first direction and the first pads are adjacent to the first side, and
the plurality of second semiconductor chips are stacked and sequentially offset opposite to the first direction and the second pads are adjacent to the second side.

8. The semiconductor package of claim 7, further comprising a first bonding wire structure connecting the first pads and the first bonding pads, and a second bonding wire structure connecting the second pads and the second bonding pads.

9. The semiconductor package of claim 1, wherein the first chip structure includes a plurality of first semiconductor chips stacked and sequentially offset from the first side in a first direction, and the second chip structure includes a plurality of second semiconductor chips stacked and sequentially offset from the second side opposite to the first direction, and
a lowest first semiconductor chip among the plurality of first semiconductor chips and a lowest second semiconductor chip among the plurality of second semiconductor chips are spaced apart from a side surface of the controller by a first distance in the first direction.

10. The semiconductor package of claim 9, wherein a first semiconductor chip stacked on an upper surface of the lowest first semiconductor chip and a second semiconductor chip stacked on an upper surface of the lowest second semiconductor chip overlap at least a portion of an upper surface of the controller in a second direction perpendicular to the first direction, and are spaced from the upper surface of the controller by a second distance greater than the first distance in the second direction.

11. The semiconductor package of claim 10, wherein the first distance is about 50 um to 100 um or less, and the second distance is about 100 um to 150 um or less.

12. The semiconductor package of claim 1, wherein the first chip structure includes a plurality of first semiconductor chips stacked and sequentially offset from the first side in a first direction, and the second chip structure includes a plurality of second semiconductor chips stacked and sequentially offset from the second side opposite to the first direction, and
a distance between a lowest first semiconductor chip among the plurality of first semiconductor chips and a lowest second semiconductor chip among the plurality of second semiconductor chips in the first direction is less than a horizontal width of the controller.

13. The semiconductor package of claim 12, wherein a highest first semiconductor chip among the plurality of first semiconductor chips and a highest second semiconductor chip among the plurality of second semiconductor chips are spaced apart from each other by a distance of about 100 um to 200 um or less in the first direction.

14. The semiconductor package of claim 1, wherein the solder resist layer includes a photosensitive resin composition.

15. A semiconductor package comprising:
a substrate including edge pads, upper pads, and a passivation layer having openings exposing the edge pads;
a solder resist layer disposed on the passivation layer of the substrate and including open regions exposing the openings, the open regions of the solder resist layer have a width greater than a width of the openings of the passivation layer;
at least one controller having an active surface with connection pads disposed thereon and a non-active surface opposite to the active surface, the active surface facing an upper surface of the solder resist layer;
a plurality of connection structures disposed between the at least one controller and the upper pads of the substrate and electrically connecting the connection pads of the at least one controller and the upper pads of the substrate; and
at least one pair of chip structures disposed on the solder resist layer and spaced apart from each other with the at least one controller disposed between the at least one pair of chip structures,
wherein the at least one pair of chip structures includes upper surface pads electrically connected to the edge pads.

16. The semiconductor package of claim 15, further comprising a bonding wire structure connecting the edge pads of the substrate and the upper surface pads of the at least one pair of chip structures.

17. The semiconductor package of claim 15, wherein the solder resist layer and the passivation layer further include first open portions penetrating through the solder resist layer and the passivation layer to expose the upper pads of the substrate, and
the plurality of connection structures are disposed within the first open portions.

18. The semiconductor package of claim 15, wherein the solder resist layer and the passivation layer include first open portions penetrating the solder resist layer and the passivation layer to expose the upper pads of the substrate,
the solder resist layer includes a second open portion on the first open portions and having a horizontal width greater than a horizontal width of the first open portions,
the at least one controller is disposed in the second open portion, and
the plurality of connection structures are disposed within the first open portions.

19. A semiconductor package comprising:
a substrate including edge pads and upper pads disposed on an upper portion;
a first solder resist layer disposed on the substrate and exposing the edge pads;
a second solder resist layer disposed on the first solder resist layer and having a step from the first solder resist layer;
at least one controller disposed on the second solder resist layer and including a plurality of connection pads disposed in a lower portion of the at least one controller;
at least one pair of chip structures disposed on the second solder resist layer, spaced apart from each other with the at least one controller disposed between the at least one pair of chip structures, the at least one pair of chip structures including upper surface pads disposed on each upper surface;
a connection structure penetrating the first solder resist layer and the second solder resist layer and electrically connecting the plurality of connection pads of the at least one controller and the upper pads of the substrate; and
a bonding wire structure electrically connecting the upper surface pads of the at least one pair of respective chip structures and the edge pads of the substrate.

20. The semiconductor package of claim 19, wherein the substrate further includes a wiring circuit electrically connecting the edge pads and the upper pads, and
the at least one controller is electrically connected to the at least one pair of chip structures through the connection structure and the wiring circuit.
